(19) United States
(12) Patent Application Publication
(10) Pub. No.: US 2022/0045116 A1
(43) Pub. Date: Feb. 10, 2022

(54) IMAGE SENSOR

(71) Applicant: SAMSUNG ELECTRONICS CO., LTD., Suwon-si (KR)

(72) Inventors: Han Seok KIM, Seoul (KR); Seung Joo NAH, Gwangju (KR); Sang Il JUNG, Seoul (KR); Hee Geun JEONG, Suwon-si (KR)

(21) Appl. No.: 17/246,923

(22) Filed: May 3, 2021

(30) Foreign Application Priority Data
Aug. 5, 2020 (KR) 10-2020-0097839

(51) Int. Cl. H01L 27/146

(52) U.S. Cl. CPC H01L 27/14636; H01L 27/14621; H01L 27/14627

(57) ABSTRACT

An image sensor includes a first substrate. A first wiring structure is disposed on the first substrate and includes a first wiring layer. A second substrate is disposed on the first wiring structure and includes a first region and a second region that are spaced apart from each other. The first region includes a photoelectric conversion element disposed therein. A conductive pattern penetrates the second region of the second substrate and extends into the first wiring layer. The conductive pattern includes a step in the first wiring layer. A lowermost surface of the conductive pattern is disposed inside the first wiring layer.

### CROSS-REFERENCE TO RELATED APPLICATION

This application claims priority under 35 U.S.C. § 119 to Korean Patent Application No. 10-2020-0097839, filed on Aug. 5, 2020 in the Korean Intellectual Property Office, the disclosure of which is incorporated by reference in its entirety herein.

### 1. Technical Field

The present inventive concepts relate to an image sensor.

### 2. Discussion of Related Art

An image sensor is a type of semiconductor device that converts optical information into electric signals. Examples of an image sensor include a charge coupled device (CCD) image sensor and a complementary metal oxide semiconductor (CMOS) image sensor.

The image sensor may be configured in the form of a package. The package may have a structure allowing light to be incident on a photo-receiving surface or sensing area while protecting the image sensor.

Recently, research has been conducted on a backside illumination (BSI) image sensor in which incident light is irradiated through a rear surface of a semiconductor substrate so that pixels formed in the image sensor may have increased light receiving efficiency and light sensitivity.

### SUMMARY

Aspects of the present inventive concepts provide an image sensor having a conductive pattern including a bottom surface that is in direct contact with a wiring layer formed in a logic circuit area. The conductive pattern has a step, thereby increasing a contact area between the wiring layer and the conductive pattern, and thus increasing the reliability of connection between the wiring layer and the conductive pattern.

According to an embodiment of the present inventive concepts, an image sensor includes a first substrate. A first wiring structure is disposed on the first substrate and includes a first wiring layer. A second substrate is disposed on the first wiring structure and includes a first region and a second region that are spaced apart from each other. The first region includes a photoelectric conversion element disposed therein. A conductive pattern penetrates the second region of the second substrate and extends into the first wiring layer. The conductive pattern includes a step in the first wiring layer. A lowermost surface of the conductive pattern is disposed inside the first wiring layer.

According to an embodiment of the present inventive concepts, an image sensor includes a first substrate. A first wiring structure is disposed on the first substrate. The first wiring structure includes a first interlayer insulating layer and a first wiring layer disposed inside the first interlayer insulating layer. A second wiring structure is disposed on the first wiring structure and includes a second wiring layer. A second substrate is disposed on the second wiring structure. The second substrate includes a first region and a second region that are spaced apart from each other. The first region includes a photoelectric conversion element disposed therein. A connection trench penetrates the second region of the second substrate, extends into the first wiring layer, and exposes at least a partial portion of the second wiring layer. A conductive pattern is disposed along a sidewall and a bottom surface of the connection trench. The conductive pattern includes a first portion directly contacting a top surface of the first wiring layer and a second portion directly contacting a top surface of the second wiring layer. The first portion of the conductive pattern includes a first bottom surface disposed inside the first wiring layer and a second bottom surface having a height difference from the first bottom surface.

According to an embodiment of the present inventive concepts, an image sensor includes a first substrate. A first wiring structure is disposed on the first substrate and includes a first wiring layer. A second wiring structure is disposed on the first wiring structure and includes a second wiring layer. A second substrate is disposed on the second wiring structure and includes a first region and a second region that are spaced apart from each other. The first region includes a photoelectric conversion element disposed therein. A connection trench penetrates the second region of the second substrate and exposes each of the first wiring layer and the second wiring layer. A conductive pattern is disposed along a sidewall and a bottom surface of the connection trench. The conductive pattern has a step in the bottom surface of the connection trench exposing the first wiring layer. The conductive pattern includes a first bottom surface that is a lowermost surface of the conductive pattern and a second bottom surface having a height difference from the first bottom surface. The first bottom surface of the conductive pattern is disposed at a higher level than a level of the bottom surface of the first wiring layer.

However, embodiments of the present inventive concepts are not restricted to the embodiments set forth herein. The above and other aspects of the present inventive concepts will become more apparent to one of ordinary skill in the art to which the present disclosure pertains by referencing the detailed description of embodiments given below.

### BRIEF DESCRIPTION OF THE DRAWINGS

The above and other aspects and features of the present inventive concepts will become more apparent by describing in detail embodiments thereof with reference to the attached drawings, in which:

FIG. 1 is a block diagram of an image sensor according to an embodiment of the present inventive concepts;

FIG. 2 is a circuit diagram of a unit pixel area of an image sensor according to an embodiment of the present inventive concepts;

FIG. 3 is a plan view of an image sensor according to an embodiment of the present inventive concepts;

FIG. 4 is a cross-sectional view taken along lines A-A′ and B-B′ of FIG. 3 according to embodiments of the present inventive concepts;

FIG. 5 is a cross-sectional view taken along lines A-A′ and C-C′ of FIG. 3 according to embodiments of the present inventive concepts;

FIG. 6 is a cross-sectional view taken along lines A-A′ and D-D′ of FIG. 3 according to embodiments of the present inventive concepts;

FIG. 7 is an enlarged view of area R1 of FIG. 5 according to an embodiment of the present inventive concepts;

FIG. 8 is an enlarged view of area R2 of FIG. 5 according to an embodiment of the present inventive concepts;

FIG. 9 is an enlarged view for describing an image sensor according to an embodiment of the present inventive concepts;

FIG. 10 is an enlarged view of an image sensor according to an embodiment of the present inventive concepts;

FIG. 11 is a cross-sectional view illustrating an image sensor according to an embodiment of the present inventive concepts;

FIG. 12 is an enlarged view of area R3 of FIG. 11 according to an embodiment of the present inventive concepts;

FIG. 13 is an enlarged view of area R4 of FIG. 11 according to an embodiment of the present inventive concepts;

FIG. 14 is a cross-sectional view illustrating an image sensor according to an embodiment of the present inventive concepts;

FIG. 15 is an enlarged view of area R5 of FIG. 14 according to an embodiment of the present inventive concepts;

FIG. 16 is a cross-sectional view illustrating an image sensor according to an embodiment of the present inventive concepts;

FIG. 17 is an enlarged view of area R6 of FIG. 16 according to an embodiment of the present inventive concepts;

FIG. 18 is a cross-sectional view illustrating an image sensor according to an embodiment of the present inventive concepts;

FIG. 19 is a cross-sectional view illustrating an image sensor according to an embodiment of the present inventive concepts;

FIG. 20 is a cross-sectional view illustrating an image sensor according to an embodiment of the present inventive concepts; and

FIG. 21 is an enlarged view of area R7 of FIG. 20 according to an embodiment of the present inventive concepts.

### DETAILED DESCRIPTION OF EMBODIMENTS

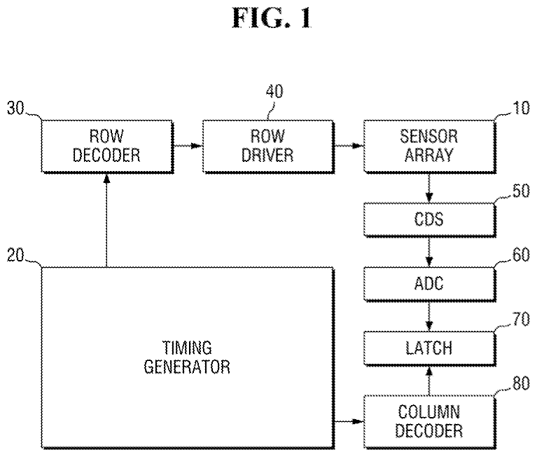

Hereinafter, an image sensor according to embodiments of the present inventive concepts will be described with reference to FIGS. 1 to 8.

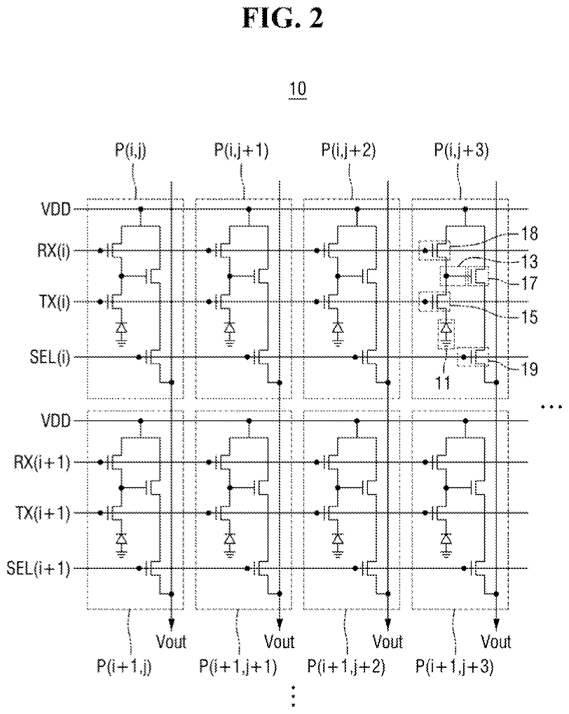

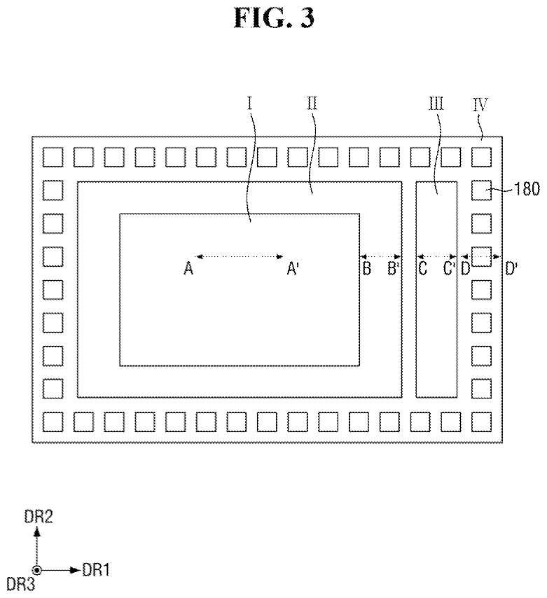

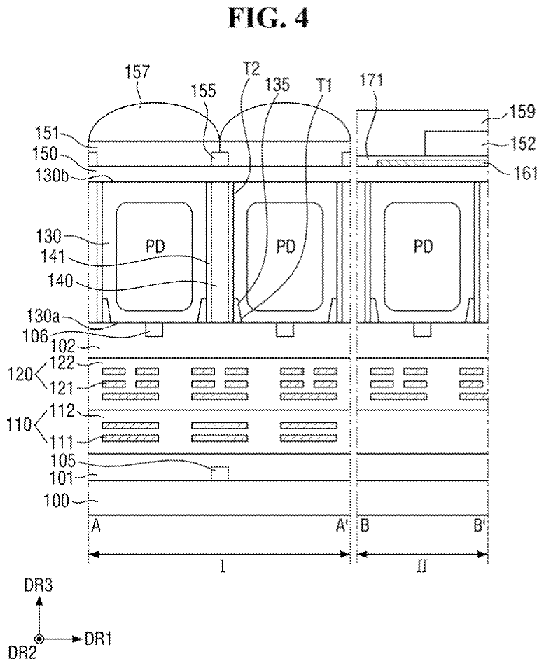

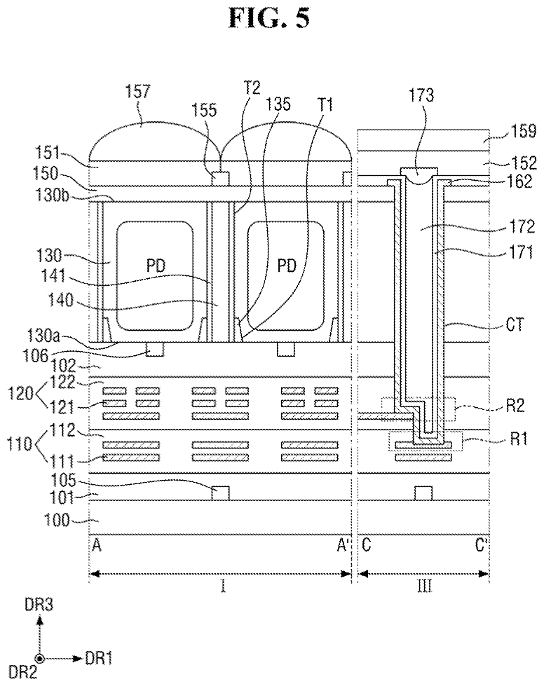

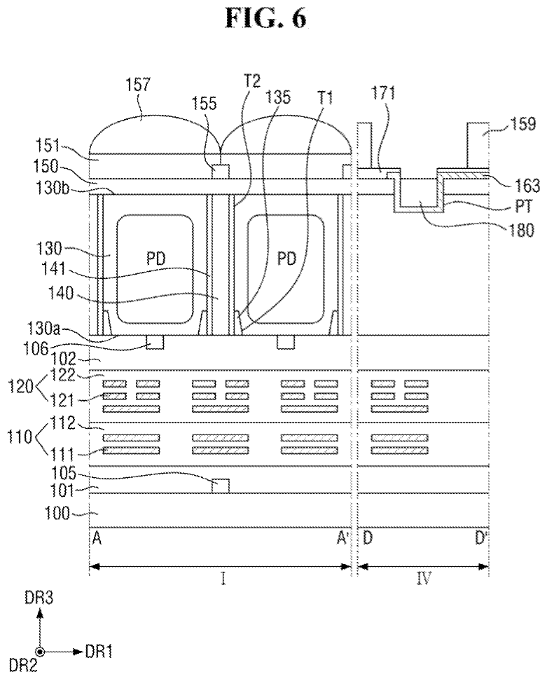

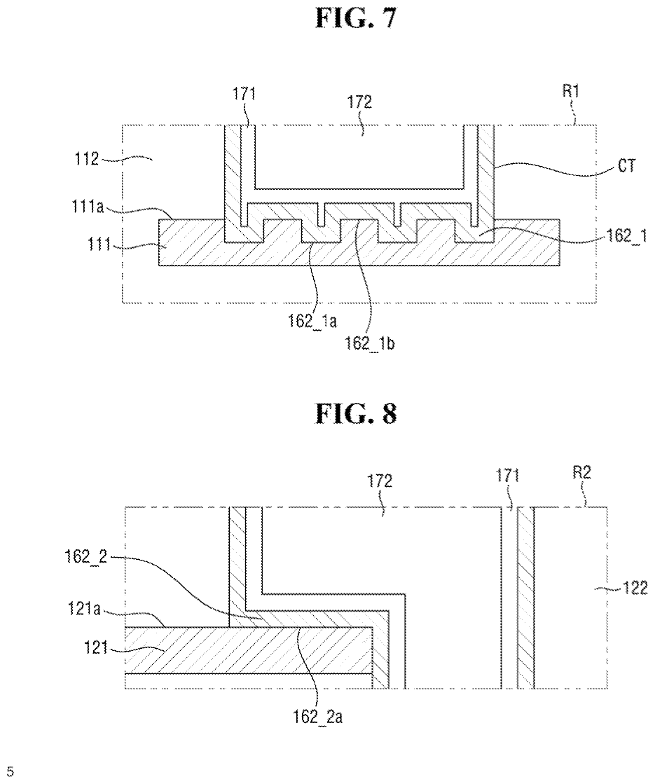

FIG. 1 is a block diagram of an image sensor according to an embodiment of the present inventive concepts. FIG. 2 is a circuit diagram of a unit pixel area of an image sensor according to an embodiment of the present inventive concepts. FIG. 3 is a schematic plan view of an image sensor according to an embodiment of the present inventive concepts. FIG. 4 is a cross-sectional view taken along lines A-A′ and B-B′ of FIG. 3. FIG. 5 is a cross-sectional view taken along lines A-A′ and C-C′ of FIG. 3. FIG. 6 is a cross-sectional view taken along lines A-A′ and D-D′ of FIG. 3. FIG. 7 is an enlarged view of area R1 of FIG. 5. FIG. 8 is an enlarged view of area R2 of FIG. 5.

Referring to FIG. 1, an image sensor according to an embodiment of the present inventive concepts comprises an active pixel sensor array 10, a timing generator 20, a row decoder 30, a row driver 40, a correlated double sampler (CDS) 50, an analog-to-digital converter (ADC) 60, a latch 70, and a column decoder 80.

The active pixel sensor array 10 includes photoelectric conversion elements and a plurality of unit pixels arranged two-dimensionally. In an embodiment, the plurality of unit pixels may perform a function of converting an optical image into an electrical output signal.

The active pixel sensor array 10 may be driven by a plurality of driving signals such as a row selection signal, a reset signal, and a charge transfer signal received from the row driver 40. Further, the converted electrical output signal may be provided to the CDS 50 through a vertical signal line.

The timing generator 20 may provide a timing signal and a control signal to the row decoder 30 and the column decoder 80.

The row driver 40 may provide the active pixel sensor array 10 with a plurality of driving signals to drive a plurality of unit pixels according to the decoding result of the row decoder 30. In general, when unit pixels are arranged in a matrix form, a driving signal may be provided to each row. However, embodiments of the present inventive concepts are not limited thereto.

The CDS 50 may receive an output signal formed in the active pixel sensor array 10 through a vertical signal line, and may hold and sample the received signal. For example, the CDS 50 may double-sample a specific noise level and a signal level according to the output signal, and output a difference level corresponding to a difference between the noise level and the signal level.

The ADC 60 may convert an analog signal corresponding to the difference level into a digital signal, and output the digital signal.

The latch 70 may latch digital signals, and the latched signals may be sequentially outputted to an image signal processor according to the decoding result of the column decoder 80.

Referring to the embodiment of FIG. 2, pixels P are arranged in a matrix to constitute the active pixel sensor array 10. For example, as shown in the embodiment of FIG. 2, the matrix may include the rows i to i+1 and the columns j to j+3. In embodiments of the present inventive concepts, the matrix may include any number of rows and columns. Each pixel P includes a photoelectric conversion element 11, a floating diffusion region 13, a charge transfer element 15, a drive element 17, a reset element 18, and a selection element 19. Their functions will be described with respect to the pixels P (i, j), P (i, j+1), P (i, j+2), P (i, j+3), . . . arranged in the i^{th} row.

The photoelectric conversion element 11 may absorb incident light and may accumulate charges corresponding to the quantity of light. In an embodiment, the photoelectric conversion element 11 may include a photodiode, a phototransistor, a photogate, a pinned photodiode, or a combination thereof. For convenience of explanation, an embodiment in which the photoelectric conversion element 11 is a photodiode is illustrated in the drawing. The photoelectric conversion element 11 may be coupled with the charge transfer element 15 that transfers the accumulated charges to the floating diffusion region 13.

The floating diffusion region (FD) 13 is a region that converts charges into a voltage, and has a parasitic capacitance, so that charges may be accumulated and stored.

The drive element 17 illustrated as a source follower amplifier may amplify a change in the electrical potential of the floating diffusion region 13 which receives the charges accumulated in the photoelectric conversion element 11 and outputs it to an output line Vout.

The reset element 18 may periodically reset the floating diffusion region 13. In an embodiment, the reset element 18 may be formed of a single MOS transistor which is driven by a bias provided via a reset line RX(i) for applying a predetermined bias (e.g., a reset signal).

When the reset element 18 is turned on by the bias provided via the reset line RX(i), a predetermined electric potential (e.g., a source voltage VDD) provided to the drain of the reset element 18 may be transferred to the floating diffusion region 13.

The selection element 19 may perform a function of selecting a pixel P to be read per row. In an embodiment, the selection element 19 may be formed of one MOS transistor which is driven by a bias (e.g., a row selection signal) provided via a row selection line SEL(i). However, embodiments of the present inventive concepts are not limited thereto.

When the selection element 19 is turned on by the bias provided via the row selection line SEL(i), a predetermined electric potential (e.g., the source voltage VDD) provided to the drain of the selection element 19 may be transferred to the drain region of the drive element 17.

A transfer line TX(i) for applying a bias to the charge transfer element 15, the reset line RX(i) for applying a bias to the reset element 18, and the row selection line SEL(i) for applying a bias to the selection element 19 may be arranged to extend substantially in parallel with each other in a row direction.

Referring to FIG. 3, the image sensor according to an embodiment of the present inventive concepts may comprise first to fourth regions I, II, 111, and IV.

The first region I and the second region II may be sensor array regions. On the plane defined by a first direction DR1 and a second direction DR2 perpendicular to the first direction DR1, the second region II may surround the first region I. For example, as shown in the embodiment of FIG. 3, the second region II may fully surround the first region I (e.g., in the first and second directions DR1, DR2).

The first region I may be an active pixel sensor region that includes active pixels for generating an active signal corresponding to the wavelength of light from the outside. The second region II may be an optical black sensor region for generating an optical black signal by blocking light from the outside.

The fourth region IV may be a pad region. As shown in the embodiment of FIG. 3, a plurality of pads 180 may be disposed in the fourth region IV. The plurality of pads 180 may exchange electrical signals with an external device. The fourth region IV may surround the second region II. For example, as shown in the embodiment of FIG. 3, the fourth region IV may entirely surround the second region (e.g., in the first and second directions DR1, DR2).

The third region III may be a connection region. For example, as shown in the embodiment of FIG. 6, the third region III may be electrically connected to a logic circuit area disposed on a bottom surface 130a of a second substrate 130. The third region III may be disposed between the second region II that is the optical black sensor region and the fourth region IV that is the pad region (e.g., in the first direction DR1).

Referring to FIGS. 3 to 8, the image sensor according to some embodiments of the present inventive concepts may include a first substrate 100, a first insulating layer 101, a second insulating layer 102, a first gate structure 105, a second gate structure 106, a first wiring structure 110, a second wiring structure 120, a second substrate 130, a photoelectric conversion element PD, a first element isolation layer 135, a second element isolation layer 140, a trench barrier layer 141, a passivation layer 150, a first color filter 151, a second color filter 152, a grid pattern 155, a microlens 157, a transparent layer 159, first to third conductive patterns 161, 162 and 163, an adhesive layer 171, a low refractive index layer 172, a photoresist 173 and the pads 180.

In an embodiment, the first substrate 100 may be a bulk silicon or silicon-on-insulator (SOI) substrate. For example, the first substrate 100 may be a silicon substrate, or may include other materials such as at least one compound selected from silicon germanium, indium antimonide, lead tellurium compound, indium arsenide, indium phosphide, gallium arsenide, and gallium antimonide. In another embodiment, the first substrate 100 may have an epitaxial layer formed on a base substrate.

The first insulating layer 101 may be disposed on the first substrate 100. For example, a bottom surface of the first insulating layer 101 may directly contact a top surface of the first substrate 100. The first insulating layer 101 may be disposed to cover the first gate structure 105 disposed on the first substrate 100. For example, as shown in the embodiment of FIG. 4, the first insulating layer 101 may cover lateral side surfaces and a top surface of the first gate structure 105. In an embodiment, the first insulating layer 101 may include at least one compound selected from silicon oxide (SiO₂), silicon nitride (SiN), silicon oxynitride (SiON) and a low dielectric constant material.

The first wiring structure 110 may be disposed on the first insulating layer 101. For example, a lower surface of the first wiring structure 110 may directly contact an upper surface of the first insulating layer 101. As shown in the embodiment of FIG. 4, the first wiring structure 110 may comprise a first interlayer insulating layer 112 and a plurality of first wiring layers 111 disposed inside the first interlayer insulating layer 112.

In an embodiment, the first wiring layer 111 may include at least one compound selected from aluminum (Al), copper (Cu), tungsten (W), cobalt (Co), ruthenium (Ru), and the like. However, embodiments of the present inventive concepts are not limited thereto. In an embodiment, the first interlayer insulating layer 112 may include at least one compound selected from silicon oxide (SiO₂), silicon nitride (SiN), silicon oxynitride (SiON) and a low dielectric constant material. However, embodiments of the present inventive concepts are not limited thereto.

The second wiring structure 120 may be disposed on the first wiring structure 110. As shown in the embodiment of FIG. 4, the second wiring structure 120 may comprise a second interlayer insulating layer 122 and a plurality of second wiring layers 121 disposed inside the second interlayer insulating layer 122.

In an embodiment, the second wiring layer 121 may include at least one compound selected from aluminum (Al), copper (Cu), tungsten (W), cobalt (Co), ruthenium (Ru), and the like. However, embodiments of the present inventive concepts are not limited thereto. The second interlayer insulating layer 122 may include at least one compound selected from silicon oxide (SiO₂), silicon nitride (SiN), silicon oxynitride (SiON) and a low dielectric constant material. However, embodiments of the present inventive concepts are not limited thereto.

The second insulating layer 102 may be disposed on the second wiring structure 120. The second insulating layer 102 may be disposed to cover a plurality of second gate structures 106 arranged on a bottom surface 103a of the second substrate 130. For example, as shown in the embodiment of FIG. 4, the second insulating layer 102 may cover bottom surfaces and lateral side surfaces of the plurality of second gate structures 106. The second gate structure 106 may be, for example, a gate of a charge transfer element, a gate of a reset element, a gate of a drive element, or the like. In an embodiment, the second insulating layer 102 may include at least one compound selected from silicon oxide (SiO₂), silicon nitride (SiN), silicon oxynitride (SiON) and a low dielectric constant material.

The second substrate 130 may be disposed on the second insulating layer 102. For example, a lower surface of the second substrate 130 may directly contact an upper surface of the second insulating layer 102. In an embodiment, the second substrate 130 may be, for example, a bulk silicon or silicon-on-insulator (SOI) substrate. The second substrate 130 may be a silicon substrate, or may include other materials such as at least one compound selected from silicon germanium, indium antimonide, lead tellurium compound, indium arsenide, indium phosphide, gallium arsenide, and gallium antimonide. In another embodiment, the second substrate 130 may have an epitaxial layer formed on a base substrate.

For convenience of explanation, the second substrate 130 is defined to comprise the first region I where the active pixel sensor region is formed, the second region II where the optical black sensor region is formed, the third region III where the connection region is formed and the fourth region IV where the pad region is formed. However, embodiments of the present inventive concepts are not limited thereto.

The photoelectric conversion element PD may be disposed inside the second substrate 130. The photoelectric conversion element PD may be disposed in the first region I of the second substrate 130. Further, the photoelectric conversion element PD may be disposed in the second region II of the second substrate 130. However, as shown in the embodiments of FIGS. 5-6, the photoelectric conversion element PD is not disposed in each of the third region III and the fourth region IV of the second substrate 130.

In an embodiment, the photoelectric conversion element PD may be, for example, a photodiode. However, embodiments of the present inventive concepts are not limited thereto. A plurality of photoelectric conversion elements PD may be disposed inside the second substrate 130. The photoelectric conversion elements PD may be separated by the first element isolation layer 135 and the second element isolation layer 140.

The first element isolation layer 135 may be disposed in a first trench T1. The bottom surface of the first element isolation layer 135 may directly contact the second insulating layer 102. For example, as shown in the embodiment of FIG. 4, the bottom surface of the first element isolation layer 135 directly contacts an upper surface of the second insulating layer 102.

The first element isolation layer 135 may include at least one compound selected from silicon oxide (SiO₂), silicon nitride (SiN), silicon carbide (SiC), silicon oxycarbide (SiOC), silicon oxynitride (SiON), and silicon oxycarbonitride (SiOCN). However, embodiments of the present inventive concepts are not limited thereto.

A second trench T2 may be formed on the first trench T1 between the photoelectric conversion elements PD. As shown in the embodiment of FIG. 4, the second trench T2 may extend from the bottom surface 130a of the second substrate 130 into the second substrate 130 in a third direction DR3. The second trench T2 may extend to a top surface 130b of the second substrate 130. However, embodiments of the present inventive concepts are not limited thereto.

As shown in the embodiment of FIG. 4, the width of the second trench T2 in the first direction DR1 may be smaller than the width of the first trench T1 in the first direction DR1.

The second element isolation layer 140 may be disposed inside the second trench T2. In an embodiment, the second element isolation layer 140 may include a material that is different from a material of the first element isolation layer 135. The second element isolation layer 140 may include a material having excellent gap-fill performance, such as polysilicon. However, embodiments of the present inventive concepts are not limited thereto.

The trench barrier layer 141 may be disposed along the sidewall of the second trench T2 in the second trench T2. For example, as shown in the embodiment of FIG. 4, the trench barrier layer 141 may be disposed between the sidewall of the second element isolation layer 140 and the second substrate 130 and between the first element isolation layer 135 and the second element isolation layer 140, in the second trench T2. Although the embodiment of FIG. 4 illustrates that the trench barrier layer 141 is conformally formed in the second trench T2, embodiments of the present inventive concepts are not limited thereto.

In an embodiment, the trench barrier layer 141 may include the same material as the passivation layer 150, for example, a high dielectric constant insulating material. However, embodiments of the present inventive concepts are not limited thereto. For example, in some other embodiments, the trench barrier layer 141 may include a material that is different from the material of the passivation layer 150.

The passivation layer 150 may be disposed on the top surface 130b of the second substrate 130. The passivation layer 150 may include, for example, a high dielectric constant insulating material. In addition, the passivation layer 150 may comprise an amorphous crystal structure. For example, at least a partial portion of the high dielectric constant insulating material comprised in the passivation layer 150 may have an amorphous crystal structure. However, embodiments of the present inventive concepts are not limited thereto.

Although it is depicted in the embodiment of FIG. 4 that the passivation layer 150 is formed as a single layer, embodiments of the present inventive concepts are not limited thereto. For example, in some other embodiments, the passivation layer 150 may further comprise a planarization layer and an anti-reflection layer. In this embodiment, the planarization layer may include, for example, at least one compound selected from a silicon oxide-based material, a silicon nitride-based material and a resin. In an embodiment, the anti-reflection layer may include a high dielectric constant material, such as, hafnium oxide (HfO₂). However, embodiments of the present inventive concepts are not limited thereto.

As shown in the embodiment of FIG. 4, the first color filter 151 may be disposed on the first region I of the second substrate 130, which is the active pixel sensor region. The first color filter 151 is not disposed in the second region II of the second substrate 130, which is the optical black sensor region.

The first color filter 151 may be disposed on the passivation layer 150. For example, as shown in the embodiment of FIG. 4, a bottom surface of the first color filter 151 may directly contact an upper surface of the passivation layer 150. The first color filter 151 may be arranged to correspond to each unit pixel. For example, the first color filters 151 may be arranged two-dimensionally (e.g., in a matrix form) in a plane defined in the first direction DR1 and the second direction DR2.

In an embodiment, the first color filter 151 may comprise a color filter of red, green, or blue according to the unit pixel. In addition, the first color filter 151 may comprise a yellow filter, a magenta filter, and a cyan filter, and may further comprise a white filter. However, embodiments of the present inventive concepts are not limited thereto.

The grid pattern 155 may be formed in a grid shape on the top surface 130b of the second substrate 130 and disposed to surround each unit pixel (e.g., in the first direction DR1 and/or second direction DR2). For example, the grid pattern 155 may be disposed between the first color filters 151 on the passivation layer 150. The grid pattern 155 may reflect incident light that is obliquely incident on the second substrate 130 to provide more incident light to the photoelectric conversion element PD.

The microlens 157 may be disposed on the first region I of the second substrate 130, which is the active pixel sensor region. The microlens 157 is not disposed in the second region II of the second substrate 130, which is the optical black sensor region or on the third region III or the fourth region IV of the second substrate 130.

The microlens 157 may be disposed on the first color filter 151. For example, a lower surface of the microlens 157 may directly contact an upper surface of the first color filter 151. As shown in the embodiment of FIG. 4, the microlens 157 may be arranged to correspond to each unit pixel. For example, one microlens 157 may be disposed on one first color filter 151. However, embodiments of the present inventive concepts are not limited thereto. For example, the microlenses 157 may be arranged two-dimensionally (e.g., in a matrix form) in a plane defined by the first direction DR1 and the second direction DR2.

The microlens 157 may have a convex shape (e.g., in a direction away from the photoelectric conversion element PD) with a predetermined curvature radius. Accordingly, the microlens 157 may condense incident light on the photoelectric conversion element PD.

In an embodiment, the microlens 157 may include, for example, an organic material such as a photosensitive resin or an inorganic material. However, embodiments of the present inventive concepts are not limited thereto.

The first conductive pattern 161 may be disposed in the second region II of the second substrate 130, which is the optical black sensor region. The first conductive pattern 161 may be disposed on the passivation layer 150.

The first conductive pattern 161 may include a metal. For example, the first conductive pattern 161 may include at least one compound selected from titanium (Ti) and tungsten (W). However, embodiment of the present inventive concepts are not limited thereto.

As shown in the embodiment of FIG. 5, a connection trench CT may be formed in the third region III of the second substrate 130, which is the connection region. The connection trench CT may penetrate the passivation layer 150, the second substrate 130, the second insulating layer 102, and the second wiring structure 120 in the third direction DR3. The connection trench CT may extend into the first wiring structure 110.

The connection trench CT may extend into the first wiring layer 111. The connection trench CT may expose at least a partial portion of the second wiring layer 121. The bottom surface of the connection trench CT may have a step.

The second conductive pattern 162 may be disposed along the sidewall and the bottom surface of the connection trench CT. For example, the second conductive pattern 162 may be conformally formed thereon. At least a partial portion of the second conductive pattern 162 may extend onto the top surface of the passivation layer 150.

As shown in the embodiments of FIGS. 7 and 8, the second conductive pattern 162 may comprise a first portion 162_1 that directly contacts a top surface ill a of the first wiring layer 111 and a second portion 162_2 that directly contacts a top surface 121a of the second wiring layer 121. For example, as shown in the embodiment of FIG. 5, the first portion 162_1 may directly contact a top surface Ill a of an uppermost first wiring layer 111 of the first wiring structure 110 and the second portion 162_2 may directly contact a top surface 121a of an uppermost second wiring layer 121 of the second wiring structure 120. However, embodiments of the present inventive concepts are not limited thereto.

As shown in the embodiment of FIG. 7, the first portion 162_1 of the second conductive pattern 162 may have a step in the first wiring layer 111. For example, the first portion 162_1 of the second conductive pattern 162 may have a first bottom surface 162_1a disposed inside (e.g., formed inside) the first wiring layer 111 and a second bottom surface 162_1b having a height difference from the first bottom surface 162_1a. For example, as shown in the embodiment of FIG. 7, the first bottom surface 162_1a, which is the lowermost surface of the second conductive pattern 162, may be disposed inside the first wiring layer 111. The second bottom surface 162_1b may be positioned at a higher level that the first bottom surface 162_1a.

The first bottom surface 162_1a of the first portion 162_1 of the second conductive pattern 162 being disposed inside the first wiring layer 111 means that the first bottom surface 162_1a of the first portion 162_1 of the second conductive pattern 162 is disposed (e.g., formed) between the bottom surface and the top surface 111a of one first wiring layer 111.

In an embodiment, the second bottom surface 162_1b of the first portion 162_1 of the second conductive pattern 162 may be disposed, for example, on the same plane as the top surface 111a of the first wiring layer 111. For example, the second bottom surface 162_1b of the first portion 162_1 may have a substantially same height as the top surface 111a of the first wiring layer 111. However, embodiments of the present inventive concepts are not limited thereto. For example, in some other embodiments, the second bottom surface 162_1b of the first portion 162_1 of the second conductive pattern 162 may be disposed inside the first wiring layer 111.

The second portion 162_2 of the second conductive pattern 162 may be disposed on the second wiring layer 121. For example, as shown in the embodiment of FIG. 8, a bottom surface 162_2a of the second portion 162_2 of the second conductive pattern 162 may directly contact a top surface 121a of the second wiring layer 121. The second portion 162_2 of the second conductive pattern 162 may have a height difference from the first portion 162_1 of the second conductive pattern 162. For example, the second portion 162_2 of the second conductive pattern 162 may be positioned at a higher level than the first portion 162_1 of the second conductive pattern 162.

Although the embodiment of FIG. 8 illustrates that the bottom surface 162_2a of the second portion 162_2 of the second conductive pattern 162 is formed on the same plane as the top surface 121a of the second wiring layer 121, embodiments of the present inventive concepts are not limited thereto. For example, in some other embodiments, the bottom surface 162_2a of the second portion 162_2 of the second conductive pattern 162 may be disposed inside the second wiring layer 121.

The second conductive pattern 162 may include a metal. For example, in an embodiment, the second conductive pattern 162 may include at least one compound selected from titanium (Ti) and tungsten (W). However, embodiments of the present inventive concepts are not limited thereto.

As shown in the embodiment of FIG. 6, a pad trench PT may be formed in the fourth region IV of the second substrate 130, which is the pad region. The pad trench PT may penetrate the passivation layer 150 in the third direction DR3 and extend into the second substrate 130.

The third conductive pattern 163 may be disposed along the sidewall and the bottom surface of the pad trench PT. For example, the third conductive pattern 163 may be conformally formed. At least a partial portion of the third conductive pattern 163 may extend onto the top surface of the passivation layer 150.

The third conductive pattern 163 may include a metal. For example, in an embodiment, the third conductive pattern 163 may include at least one compound selected from titanium (Ti) and tungsten (W). However, embodiments of the present inventive concepts are not limited thereto.

The pad 180 may fill the inside of the pad trench PT on the third conductive pattern 163. For example, as shown in the embodiment of FIG. 6, the pad 180 may directly contact inner lateral side surfaces and a bottom surface of the third conductive pattern 163. The pad 180 may include a conductive material.

The adhesive layer 171 may be disposed on the passivation layer 150. The adhesive layer 171 may be disposed on the passivation layer 150 to cover the first conductive pattern 161 and the second conductive pattern 162. In addition, the adhesive layer 171 may be disposed to cover the partial portion of the third conductive pattern 163 that is disposed on a top surface of the passivation layer 150.

As shown in the embodiment of FIG. 5, the adhesive layer 171 may be disposed on the second conductive pattern 162 in the connection trench CT. For example, the adhesive layer 171 may be formed conformally in the connection trench CT. However, embodiments of the present inventive concepts are not limited thereto.

In an embodiment, the adhesive layer 171 may include, for example, aluminum oxide (Al₂O₃). However, embodiments of the present inventive concepts are not limited thereto.

The low refractive index layer 172 may be disposed on the adhesive layer 171 in the connection trench CT. The low refractive index layer 172 may fill the inside of the connection trench CT. In an embodiment, the low refractive index layer 172 may include, for example, at least one material selected from oxide, nitride, or oxynitride. However, embodiments of the present inventive concepts are not limited thereto.

The photoresist 173 may be disposed on the low refractive index layer 172. For example, the photoresist 173 may be disposed on an upper portion of the low refractive index layer 172. A partial portion of the photoresist 173 may be disposed to protrude from the top surface of the adhesive layer 171. However, embodiments of the present inventive concepts are not limited thereto. For example, in some embodiments, the photoresist 173 may not protrude from the top surface of the adhesive layer 171 or may be omitted.

The second color filter 152 may be disposed in the second region II of the second substrate 130, which is the optical black sensor region and in the third region III of the second substrate 130, which is the connection region. The second color filter 152 may be disposed on the adhesive layer 171. The second color filter 152 is not disposed in the fourth region IV of the second substrate 130, which is the pad region.

For example, as shown in the embodiments of FIGS. 4 and 5 the second color filter 152 may directly contact the top surface of the adhesive layer 171. For example, the top surface of the second color filter 152 may be formed to be higher than the top surface of the first color filter 151. However, embodiment of the present inventive concepts are not limited thereto. For example, in an embodiment, the second color filter 152 may comprise, for example, a blue color filter, etc.

The transparent layer 159 may be disposed on the adhesive layer 171 and the second color filter 152. For example, the transparent layer 159 may be disposed to completely cover the second color filter 152, such an upper surface of the second color filter 152. However, embodiments of the present inventive concepts are not limited thereto. The transparent layer 159 is not disposed on the pad 180. The transparent layer 159 may include, for example, a material that transmits light.

In the image sensor according to an embodiment of the present inventive concepts, the bottom surfaces 162_1a and 162_1b of the second conductive pattern 162 that directly contact the first wiring layer 111 are formed to have the height difference, thereby increasing the contact area between the first wiring layer 111 and the second conductive pattern 162. Therefore, it is possible to increase the reliability of the electrical connection between the first wiring layer 111 and the second conductive pattern 162.

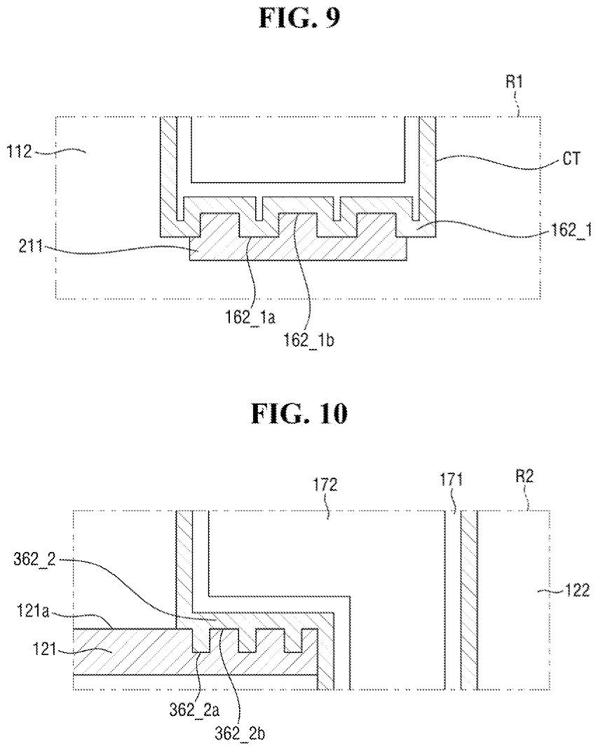

Hereinafter, an image sensor according to some other embodiments of the present inventive concepts will be described with reference to FIG. 9. Differences from the image sensor shown in the embodiments of FIGS. 1 to 8 will be mainly described and a description of substantially similar elements will be omitted for convenience of explanation.

FIG. 9 is an enlarged view of area R1 of FIG. 5 for describing an image sensor according to an embodiment of the present inventive concepts.

Referring to the embodiment of FIG. 9, in the image sensor according to an embodiment of the present inventive concepts, at least a partial portion of the first bottom surface 162_1a of the first portion 162_1 of the second conductive pattern 162 may directly contact the first interlayer insulating layer 112. The remaining portion of the first bottom surface 162_1a of the first portion 162_1 of the second conductive pattern 162 may be disposed in a first wiring layer 211.

The width of the first portion 162_1 of the second conductive pattern 162 in the first direction DR1 may be greater than the width of the first wiring layer 211 in the first direction DR1 which directly contacts a partial portion of the first portion 162_1 of the second conductive pattern 162.

Hereinafter, an image sensor according to an embodiment of the present inventive concepts will be described with reference to FIG. 10. Differences from the image sensor shown in FIGS. 1 to 8 will be mainly described and a description of substantially similar elements will be omitted for convenience of explanation.

FIG. 10 is an enlarged view of area R2 of FIG. 5 for describing an image sensor according to an embodiment of the present inventive concepts.

Referring to FIG. 10, in the image sensor according to an embodiment of the present inventive concepts, a second portion 362_2 of the second conductive pattern 162 may comprise a step in the second wiring layer 121.

For example, the second portion 362_2 of the second conductive pattern 162 may include a third bottom surface 362_2a disposed inside the second wiring layer 121 and a fourth bottom surface 362_2b having a height difference from the third bottom surface 362_2a. For example, the fourth bottom surface 362_2b may be disposed at a higher level than the third bottom surface 362_2a.

The third bottom surface 362_2a of the second portion 362_2 of the second conductive pattern 162 being disposed inside the second wiring layer 121 means that the third bottom surface 362_2a of the second portion 362_2 of the second conductive pattern 162 is disposed between the bottom surface and the top surface 121a of one second wiring layer 121.

The fourth bottom surface 362_2b of the second portion 362_2 of the second conductive pattern 162 may be formed, for example, on the same plane as the top surface 121a of the second wiring layer 121. For example, the fourth bottom surface 362_2b of the second portion 362_2 may have a substantially same height as the top surface 121a of the second wiring layer 121. However, embodiments of the present inventive concepts are not limited thereto. For example, in some other embodiments, the fourth bottom surface 362_2b of the second portion 362_2 of the second conductive pattern 162 may be disposed inside the second wiring layer 121.

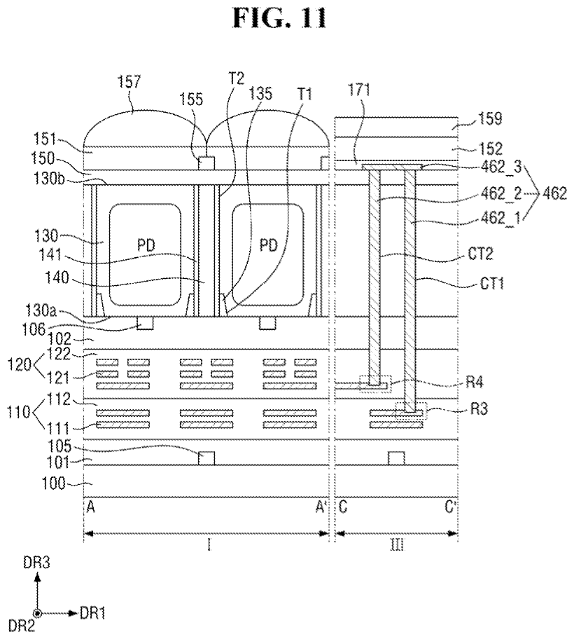

Hereinafter, an image sensor according to embodiments of the present inventive concepts will be described with reference to FIGS. 11 to 13. Differences from the image sensor shown in FIGS. 1 to 8 will be mainly described and a description of substantially similar elements will be omitted for convenience of explanation.

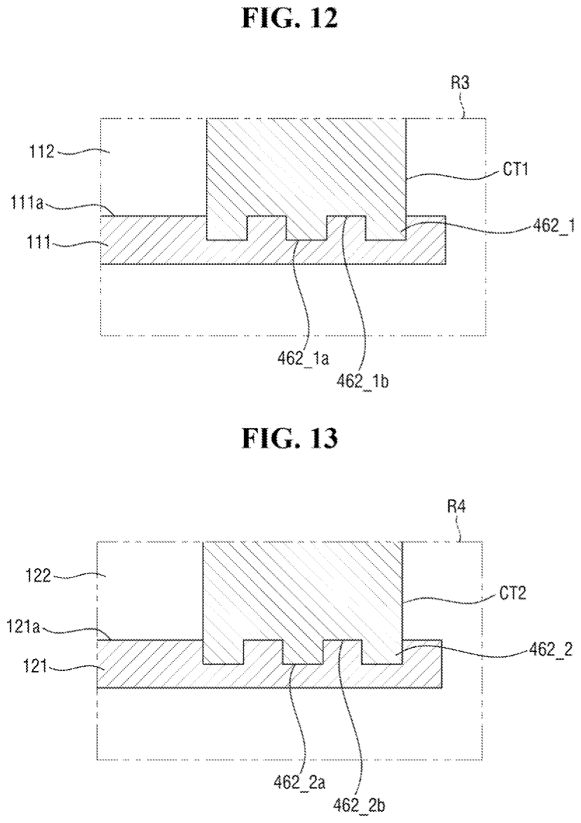

FIG. 11 is a cross-sectional view illustrating an image sensor according to an embodiment of the present inventive concepts. FIG. 12 is an enlarged view of area R3 of FIG. 11. FIG. 13 is an enlarged view of area R4 of FIG. 11.

Referring to FIGS. 11 to 13, in the image sensor according to embodiments of the present inventive concepts, a second conductive pattern 462 may comprise a first portion 462_1, a second portion 462_2, and a third portion 462_3.

A first connection trench CT1 may penetrate the passivation layer 150, the second substrate 130, the second insulating layer 102, and the second wiring structure 120 in the third direction DR3. The first connection trench CT1 may extend into the first wiring structure 110.

The first portion 462_1 of the second conductive pattern 462 may be disposed in the first connection trench CT1. As illustrated in the embodiment of FIG. 12, the first portion 462_1 of the second conductive pattern 462 may have a step in the first wiring layer 111. For example, the first portion 462_1 of the second conductive pattern 462 may include a first bottom surface 462_1a disposed inside the first wiring layer 111 and a second bottom surface 462_1b having a height difference from the first bottom surface 462_1a. For example, as shown in the embodiment of FIG. 12, the second bottom surface 462_1b may be disposed at a higher level than the first bottom surface 462_1a.

A second connection trench CT2 may penetrate the passivation layer 150, the second substrate 130, and the second insulating layer 102 in the third direction DR3. The second connection trench CT2 may extend into the second wiring structure 120. Unlike the first connection trench CT1, the second connection trench CT2 may not extend into the first wiring structure 110. The second connection trench CT2 may be spaced apart from the first connection trench CT1. For example, a bottom surface of the second connection trench CT2 may be disposed above a bottom surface of the first connection trench CT1.

The second portion 462_2 of the second conductive pattern 462 may be disposed in the second connection trench CT2. For example, as illustrated in the embodiment of FIG. 13, the second portion 462_2 of the second conductive pattern 462 may have a step in the second wiring layer 121. For example, the second portion 462_2 of the second conductive pattern 462 may comprise a third bottom surface 462_2a disposed inside the second wiring layer 121 and a fourth bottom surface 462_2b having a height difference from the third bottom surface 462_2a. For example, as shown in the embodiment of FIG. 13, the fourth bottom surface 462_2b may be disposed at a higher level than the third bottom surface 462_2a.

The second portion 462_2 of the second conductive pattern 462 may be spaced apart from the first portion 462_1 of the second conductive pattern 462 (e.g., in the first direction DR1). For example, as shown in the embodiment of FIG. 11, partial portions of the passivation layer 150, the second substrate 130, the second insulating layer 102 and the second interlayer insulating layer 122 may be disposed between the first portion 462_1 and the second portion 462_2 of the second conductive pattern 462.

The third portion 462_3 of the second conductive pattern 462 may be disposed on the top surface of the passivation layer 150. For example, as shown in the embodiment of FIG. 11, a bottom surface of the third portion 462_3 of the second conductive pattern 462 may directly contact a top surface of the passivation layer 150. The third portion 462_3 of the second conductive pattern 462 may extend longitudinally in the first direction DR1 and may connect the first portion 462_1 of the second conductive pattern 462 to the second portion 462_2 of the second conductive pattern 462.

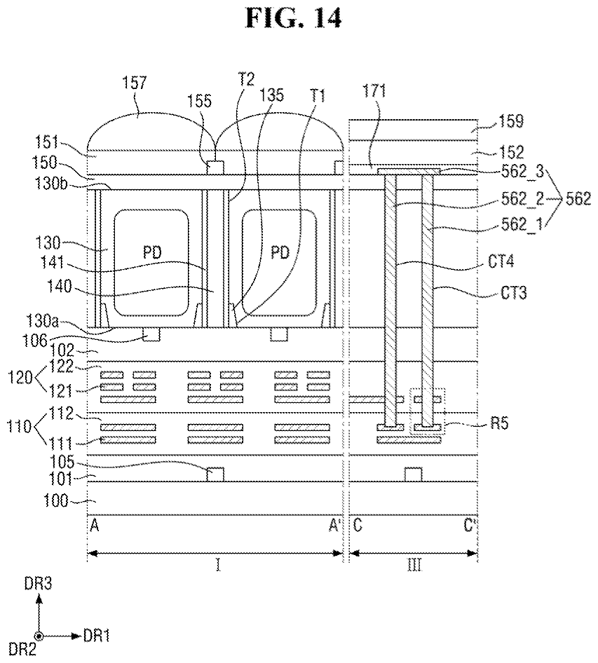

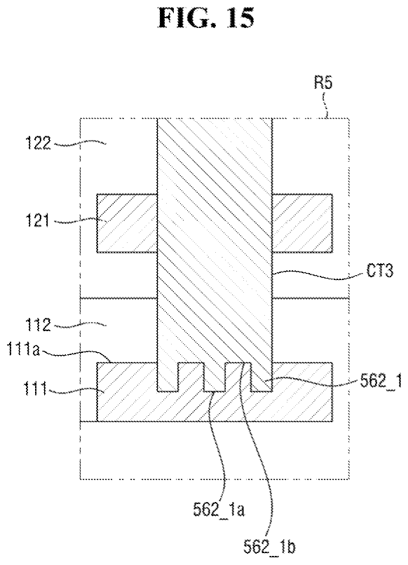

Hereinafter, an image sensor according to embodiments of the present inventive concepts will be described with reference to FIGS. 14 and 15. Differences from the image sensor shown in FIGS. 1 to 8 will be mainly described and a description of substantially similar elements will be omitted for convenience of explanation.

FIG. 14 is a cross-sectional view illustrating an image sensor according to an embodiment of the present inventive concepts. FIG. 15 is an enlarged view of area R5 of FIG. 14.

Referring to FIGS. 14 and 15, in the image sensor according to embodiments of the present inventive concepts, a second conductive pattern 562 may include a first portion 562_1, a second portion 562_2, and a third portion 562_3.

A third connection trench CT3 may penetrate the passivation layer 150, the second substrate 130, the second insulating layer 102, and the second wiring structure 120 in the third direction DR3. The third connection trench CT3 may extend into the first wiring structure 110. The third connection trench CT3 may penetrate the second wiring layer 121 as illustrated in the embodiment of FIG. 14. However, embodiments of the present inventive concepts are not limited thereto.

The first portion 562_1 of the second conductive pattern 562 may be disposed in the third connection trench CT3. As shown in the embodiment of FIG. 15, the first portion 562_1 of the second conductive pattern 562 may have a step in the first wiring layer 111. For example, the first portion 562_1 of the second conductive pattern 562 may include a first bottom surface 562_1a disposed inside the first wiring layer 111 and a second bottom surface 562_1b having a height difference from the first bottom surface 562_1a. For example, the second bottom surface 562_1b may be disposed at a higher level than the first bottom surface 562_1a.

A fourth connection trench CT4 may penetrate the passivation layer 150, the second substrate 130, the second insulating layer 102, and the second wiring structure 120 in the third direction DR3. The fourth connection trench CT4 may extend into the first wiring structure 110. The fourth connection trench CT4 may penetrate the second wiring layer 121 as illustrated in the embodiment of FIG. 14. However, embodiments of the present inventive concepts are not limited thereto. For example, in an embodiment, the fourth connection trench CT4 may be spaced apart from the third connection trench CT3 (e.g., in the third direction DR3).

The second portion 562_2 of the second conductive pattern 562 may be disposed in the fourth connection trench CT4. The second portion 562_2 of the second conductive pattern 562 may have a structure similar to the first portion 562_1 of the second conductive pattern 562 and a repeated description will be omitted for convenience of explanation.

The second portion 562_2 of the second conductive pattern 562 may be spaced apart from the first portion 562_1 of the second conductive pattern 562 (e.g., in the first direction DR1). For example, partial portions of the passivation layer 150, the second substrate 130, the second insulating layer 102, the second interlayer insulating layer 122 and the first interlayer insulating layer 112 may be disposed between the first portion 562_1 and the second portion 562_2 of the second conductive pattern 562.

The third portion 562_3 of the second conductive pattern 562 may be disposed on the top surface of the passivation layer 150. For example, a lower surface of the third portion 562_3 of the second conductive pattern 562 may directly contact a top surface of the passivation layer 150. The third portion 562_3 of the second conductive pattern 562 may connect the first portion 562_1 of the second conductive pattern 562 to the second portion 562_2 of the second conductive pattern 562.

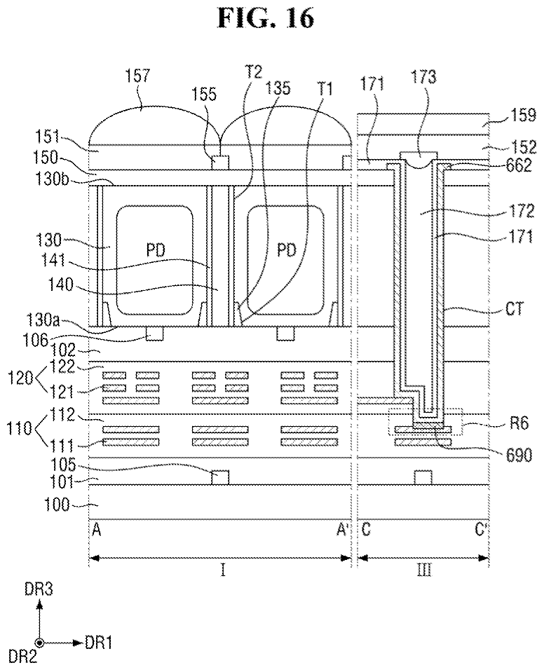

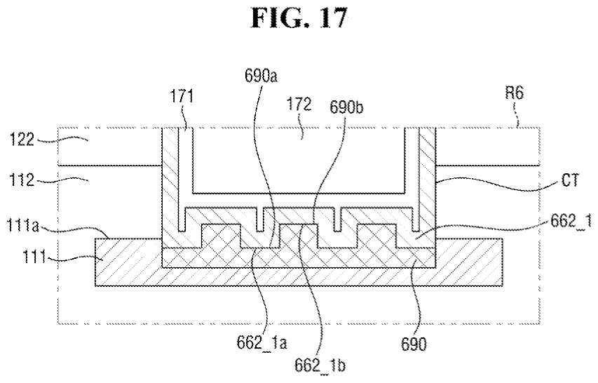

Hereinafter, an image sensor according to some embodiments of the present inventive concepts will be described with reference to FIGS. 16 and 17. Differences from the image sensor shown in FIGS. 1 to 8 will be mainly described and a repeated description of substantially similar elements will be omitted for convenience of explanation.

FIG. 16 is a cross-sectional view illustrating an image sensor according to an embodiment of the present inventive concepts. FIG. 17 is an enlarged view of area R6 of FIG. 16.

Referring to FIGS. 16 and 17, in the image sensor according to an embodiment of the present inventive concepts, a metal layer 690 may be disposed between the first wiring layer 111 and the lowermost surface of a second conductive pattern 662. For example, the metal layer 690 may be disposed between the first wiring layer 111 and first and second bottom surfaces 662_1a and 662_1b of the first portion 662_1 of the second conductive pattern 662.

The metal layer 690 may be disposed in the connection trench CI′. The metal layer 690 may be arranged along the bottom surface of the connection trench CT.

As shown in the embodiment of FIG. 17, the metal layer 690 may comprise a first top surface 690a disposed inside the first wiring layer 111 and a second top surface 690b having a height difference from the first top surface 690a. For example, as shown in the embodiment of FIG. 17, the second top surface 690b of the metal layer 690 may be disposed at a higher level than the first top surface 690a of the metal layer. The second top surface 690b of the metal layer 690 may be disposed higher than the top surface of the first wiring layer 111. However, embodiments of the present inventive concepts are not limited thereto. For example, in other embodiments, the second top surface 690b of the metal layer 690 may be disposed inside the first wiring layer 111. In still some other embodiments, the second top surface 690b of the metal layer 690 may be formed on the same plane as the top surface 111a of the first wiring layer 111.

In an embodiment, the metal layer 690 may include at least one compound selected from aluminum (Al), copper (Cu), tungsten (W), cobalt (Co), ruthenium (Ru), and the like. However, embodiments of the present inventive concepts are not limited thereto.

The first and second bottom surfaces 662_1a and 662_1b of the first portion 662_1 of the second conductive pattern 662, which are in direct contact with the metal layer 690, may have a height difference. For example, the first portion 662_1 of the second conductive pattern 662 may include the first bottom surface 662_1a disposed inside the first wiring layer 111 and the second bottom surface 662_1b having the height difference from the first bottom surface 662_1a. For example, the second bottom surface 662_1b may be disposed at a higher level than the first bottom surface 662_1a. The first bottom surface 662_1a of the first portion 662_1 of the second conductive pattern 662 may directly contact the first top surface 690a of the metal layer 690. In addition, the second bottom surface 662_1b of the first portion 662_1 of the second conductive pattern 662 may directly contact the second top surface 690b of the metal layer 690.

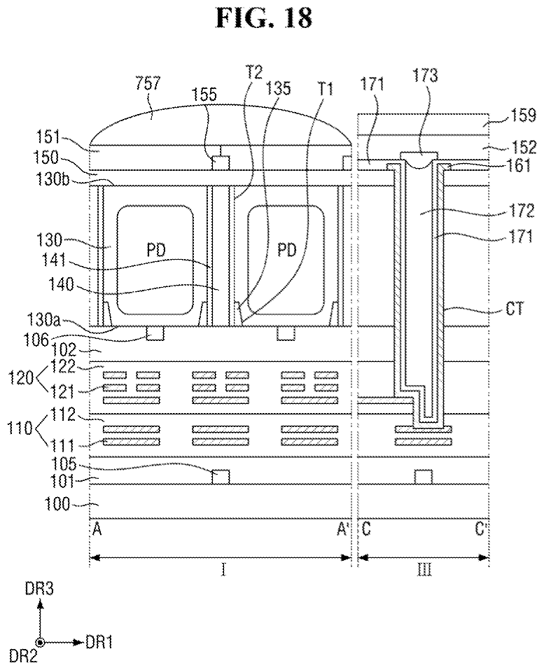

Hereinafter, an image sensor according to an embodiment of the present inventive concepts will be described with reference to FIG. 18. Differences from the image sensor shown in the embodiments of FIGS. 1 to 8 will be mainly described and a description of substantially similar elements will be omitted for convenience of explanation.

FIG. 18 is a cross-sectional view illustrating an image sensor according to an embodiment of the present inventive concepts.

Referring to FIG. 18, the image sensor according to an embodiment of the present inventive concepts may include one microlens 757 disposed on at least two first color filters 151.

Although the cross-sectional view of FIG. 18 shows one microlens 757 disposed on two first color filters 151 adjacent to each other in the first direction DR1, in an embodiment, the microlens 757 may be disposed on four adjacent first color filters 151 on the plane defined by the first direction DR1 and the second direction DR2. In another embodiment, the microlens 757 may be disposed on nine adjacent first color filters 151 on the plane defined by the first direction DR1 and the second direction DR2.

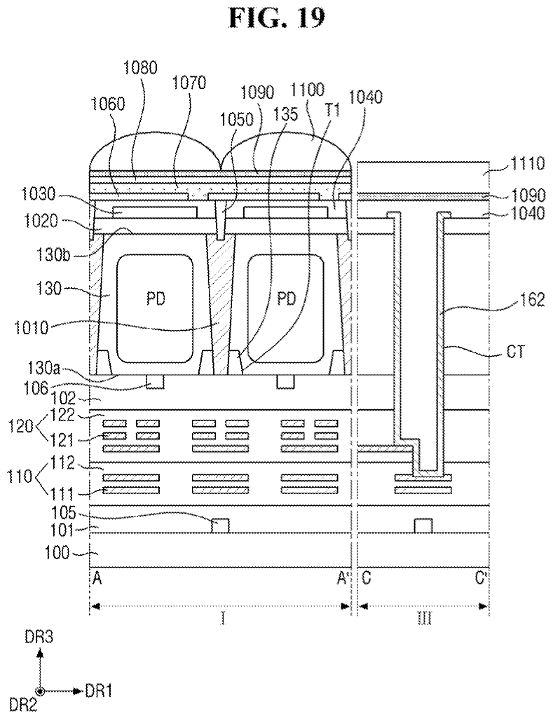

Hereinafter, an image sensor according to an embodiment of the present inventive concepts will be described with reference to FIG. 19. Differences from the image sensor shown in FIGS. 1 to 8 will be mainly described and a description of substantially similar elements will be omitted for convenience of explanation.

FIG. 19 is a cross-sectional view illustrating an image sensor according to an embodiments of the present inventive concepts.

Referring to FIG. 19, the image sensor according to an embodiment of the present inventive concepts may include a via 1010, a passivation layer 1020, a first color filter 1030, a third interlayer insulating layer 1040, a contact 1050, a lower electrode 1060, an organic photoelectric conversion layer 1070, an upper electrode 1080, a protective layer 1090, a microlens 1100, and a transparent layer 1110.

The via 1010 may penetrate the top surface 130b of the second substrate 130 in the third direction DR3 and extend into the second substrate 130 in the first region I. Although the embodiment of FIG. 19 illustrates that the via 1010 is formed as a single layer, this is for convenience of description, and the present inventive concepts are not limited thereto.

In an embodiment, the via 1010 may include, for example, a via conductive layer and a via barrier layer. The via barrier layer may be disposed along a sidewall and a bottom surface of a trench where the via 1010 is formed. In an embodiment, the via barrier layer may include at least one compound selected from silicon oxide (SiO₂), silicon nitride (SiN), silicon oxynitride (SiON) and a low dielectric constant material.

The via conductive layer may be disposed on the via barrier layer to fill the trench where the via 1010 is formed. The via conductive layer may include, for example, polysilicon. However, embodiments of the present inventive concepts are not limited thereto.

For example, in some other embodiments, the via conductive layer may include at least one compound selected from carbon (C), silver (Ag), cobalt (Co), tantalum (Ta), indium (In), tin (Sn), zinc (Zn), manganese (Mn), titanium (Ti), magnesium (Mg), chromium (Cr), germanium (Ge), strontium (Sr), platinum (Pt), magnesium (Mg), aluminum (Al), and zirconium (Zr).

The passivation layer 1020 may be disposed on the top surface 130b of the second substrate 130. The third interlayer insulating layer 1040 may be disposed on the top surface of the passivation layer 1020. The third interlayer insulating layer 1040 may completely fill the inside of the connection trench CT on the second conductive pattern 162. In an embodiment, the third interlayer insulating layer 1040 may include at least one compound selected from silicon oxide (SiO₂), silicon nitride (SiN), silicon oxynitride (SiON) and a low dielectric constant material. However, embodiments of the present inventive concepts are not limited thereto.

The contact 1050 may penetrate the third interlayer insulating layer 1040 and the passivation layer 1020 in the third direction DR3. The contact 1050 may extend into the via 1010. For example, a lower surface of the contact may be lower than an upper surface of the via 1010.

Although the embodiment of FIG. 19 illustrates that the contact 1050 is formed as a single layer, this is for convenience of description, and the present inventive concepts are not limited thereto.

In an embodiment, the contact 1050 may comprise, for example, a contact conductive layer and a contact barrier layer. The contact barrier layer may be formed along a sidewall and a bottom surface of a trench where the contact 1050 is formed. In an embodiment, the contact barrier layer may include at least one compound selected from titanium (Ti), titanium nitride (TiN), tantalum (Ta), tantalum nitride (TaN), tantalum carbonitride (TaCN), tungsten (W), tungsten nitride (WN), tungsten carbonitride (WCN), zirconium (Zr), zirconium nitride (ZrN), vanadium (V), vanadium nitride (VN), niobium (Nb), and niobium nitride (NbN). However, embodiments of the present inventive concepts are not limited thereto.

The contact conductive layer may be disposed on the contact barrier layer to fill the trench where the contact 1050 is formed. In an embodiment, the contact conductive layer may include at least one compound selected from titanium (Ti), titanium nitride (TiN), and tungsten (W). However, embodiments of the present inventive concepts are not limited thereto.

For example, in some other embodiments, the contact conductive layer may include, for example, at least one compound selected from carbon (C), silver (Ag), cobalt (Co), tantalum (Ta), indium (In), tin (Sn), zinc (Zn), manganese (Mn), magnesium (Mg), chromium (Cr), germanium (Ge), strontium (Sr), platinum (Pt), aluminum (Al), and zirconium (Zr).

The first color filter 1030 may be disposed on the first region I of the second substrate 130, which is the active pixel sensor region. The first color filter 1030 may be disposed in the third interlayer insulating layer 1040 on the top surface of the passivation layer 1020. The first color filter 1030 may be disposed on at least one lateral side of the contact 1050. For example, as shown in the embodiment of FIG. 19, the first color filter 1030 is disposed on both lateral sides of the contact 1050. The top surface of the first color filter 1030 may be formed to be lower than the top surface of the third interlayer insulating layer 1040. However, embodiments of the present inventive concepts are not limited thereto.

A plurality of lower electrodes 1060 may be disposed on the third interlayer insulating layer 1040. Each of the lower electrodes 1060 may be electrically connected to the contact 1050.

In an embodiment, the lower electrodes 1060 may be a transparent electrode. For example, the lower electrode 1060 may include at least one compound selected from indium tin oxide (ITO), zinc oxide (ZnO), tin oxide (SnO₂), antimony-doped tin oxide (ATO), aluminum-doped zinc oxide (AZO), gallium-doped zinc oxide (GZO), titanium dioxide (TiO₂) and fluorine-doped tin oxide (FTO). However, embodiments of the present inventive concepts are not limited thereto.

The organic photoelectric conversion layer 1070 may be disposed on the first color filter 1030 and may cover the lower electrodes 1060. The organic photoelectric conversion layer 1070 may generate photocharges in proportion to the amount of light incident from the outside. For example, the organic photoelectric conversion layer 1070 may receive light and convert the optical signal into an electrical signal.

The upper electrode 1080 may be disposed on the organic photoelectric conversion layer 1070. In an embodiment, the upper electrode 1080 may be a transparent electrode. For example, the upper electrode 1080 may include at least one compound selected from indium tin oxide (ITO), zinc oxide (ZnO), tin oxide (SnO₂), antimony-doped tin oxide (ATO), aluminum-doped zinc oxide (AZO), gallium-doped zinc oxide (GZO), titanium dioxide (TiO₂) and fluorine-doped tin oxide (FTO). However, embodiments of the present inventive concepts are not limited thereto.

In an embodiment, the upper electrode 1080 may include the same material as the lower electrode 1060. However, embodiments of the present inventive concepts are not limited thereto. For example, in some other embodiments, the upper electrode 1080 may include a different material than the lower electrode 1060.

The protective layer 1090 may be disposed on the upper electrode 1080. The embodiment of FIG. 19 illustrates that the protective layer 1090 is formed as a single layer for convenience of description. However, embodiments of the present inventive concepts are not limited thereto.

The protective layer 1090 may be arranged along the top surface of the third interlayer insulating layer 1040 in the third region III of the second substrate 130, which is the connection region.

The microlens 1100 may be disposed on the protective layer 1090 in the first region I. The transparent layer 1110 may be disposed on the protective layer 1090 in the third region III of the second substrate 130, which is the connection region.

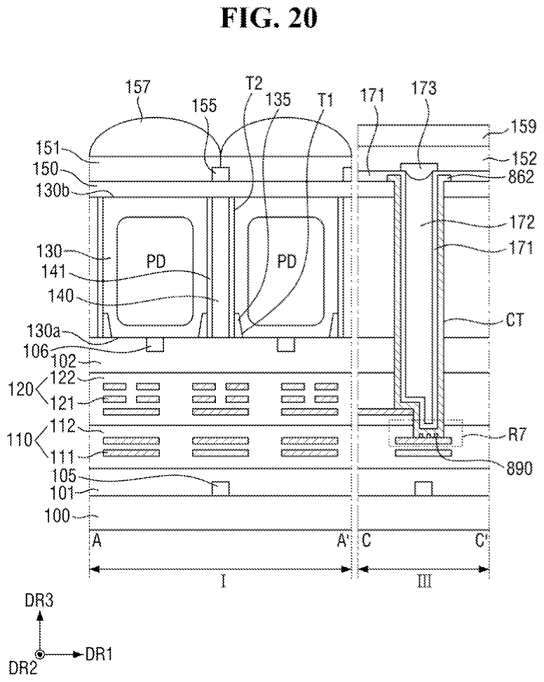

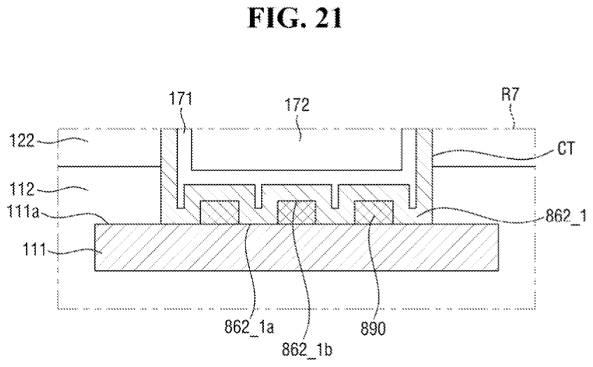

Hereinafter, an image sensor according to embodiments of the present inventive concepts will be described with reference to FIGS. 20 and 21. Differences from the image sensor shown in FIGS. 1 to 8 will be mainly described and a description of substantially similar elements will be omitted for convenience of explanation.

FIG. 20 is a cross-sectional view illustrating an image sensor according to an embodiment of the present inventive concepts. FIG. 21 is an enlarged view of area R7 of FIG. 20.

Referring to FIGS. 20 and 21, the image sensor according to embodiments of the present inventive concepts may include a metal layer 890 disposed between a second conductive pattern 862 and the first wiring layer 111. For example, the metal layer 890 may be disposed between the first wiring layer 111 and a second bottom surface 862_1b of a first portion 862_1 of the second conductive pattern 862. The metal layer 890 may be disposed on the top surface 111a of the first wiring layer 111. For example, a lower surface of the metal layer 890 may directly contact the top surface 111a of the first wiring layer 111.

The metal layer 890 may be disposed in the connection trench CT. The metal layer 890 may be disposed on the bottom surface of the connection trench Cl′, which exposes the first wiring layer 111. As shown in the embodiment of FIG. 21, a plurality of metal layers 890 may be disposed to be spaced apart from each other (e.g., in the first direction DR1 and/or second direction DR2) on the bottom surface of the connection trench CT.

In an embodiment, the metal layer 890 may include at least one compound selected from aluminum (Al), copper (Cu), tungsten (W), cobalt (Co), ruthenium (Ru), and the like. However, embodiments of the present inventive concepts are not limited thereto.

The second conductive pattern 862 may be disposed along the sidewall and the bottom surface of the connection trench CT. The second conductive pattern 862 may be disposed along the top surface of the first wiring layer 111 exposed by the bottom surface of the connection trench CT, and along the sidewall and the top surface of the metal layer 890.

As shown in the embodiment of FIG. 21, the first portion 862_1 of the second conductive pattern 862 may comprise a first bottom surface 862_1a that directly contacts the top surface 111a of the first wiring layer 111, and a second bottom surface 862_1b that directly contacts the top surface of the metal layer 890. The first bottom surface 862_1a of the first portion 862_1 of the second conductive pattern 862 may have a height difference from the second bottom surface 862_1b of the first portion 862_1 of the second conductive pattern 862. For example, the first bottom surface 862_1a may be disposed at a lower height than the second bottom surface 862_1b. In an embodiment, the first bottom surface 862_1a of the first portion 862_1 of the second conductive pattern 862, which is the lowermost surface of the second conductive pattern 862, may be formed to be higher than the bottom surface of the first wiring layer 111. For example, the first bottom surface 862_1a may have a substantially same height as a top surface of the first wiring layer 111.

In concluding the detailed description, those skilled in the art will appreciate that many variations and modifications can be made to the embodiments without substantially departing from the principles of the present inventive concepts. Therefore, the disclosed embodiments of the present inventive concepts are used in a generic and descriptive sense only and not for purposes of limitation.

What is claimed is:

1. An image sensor comprising:
a first substrate;
a first wiring structure disposed on the first substrate and including a first wiring layer;
a second substrate disposed on the first wiring structure and including a first region and a second region that are spaced apart from each other, the first region including a photoelectric conversion element disposed therein; and
a conductive pattern penetrating the second region of the second substrate and extending into the first wiring layer, the conductive pattern including a step in the first wiring layer,
wherein a lowermost surface of the conductive pattern is disposed inside the first wiring layer.

2. The image sensor of claim 1, further comprising:
a second wiring structure disposed between the first wiring structure and the second substrate and including a second wiring layer,
wherein the conductive pattern penetrates the second wiring structure, the conductive pattern includes a first portion directly contacting a top surface of the first wiring layer and a second portion directly contacting a top surface of the second wiring layer.

3. The image sensor of claim 2, wherein:
the first portion of the conductive pattern comprises a first bottom surface disposed inside the first wiring layer; and
a second bottom surface having a height difference from the first bottom surface.

4. The image sensor of claim 3, wherein a height of the second bottom surface of the first portion of the conductive pattern is substantially same as a height of the top surface of the first wiring layer.

5. The image sensor of claim 2, wherein the second portion of the conductive pattern includes a third bottom surface disposed inside the second wiring layer and a fourth bottom surface having a height difference from the third bottom surface.

6. The image sensor of claim 2, wherein a partial portion of the second substrate is disposed between the first portion of the conductive pattern and the second portion of the conductive pattern.

7. The image sensor of claim 1, further comprising:
a second wiring structure disposed between the first wiring structure and the second substrate and including a second wiring layer,
wherein the conductive pattern includes a first portion and a second portion, each of the first and second portions penetrates the second wiring layer and extends into the first wiring layer, and
wherein a partial portion of the second substrate is disposed between the first portion of the conductive pattern and the second portion of the conductive pattern.

8. The image sensor of claim 1, further comprising:
a metal layer disposed between the lowermost surface of the conductive pattern and the first wiring layer,
wherein the metal layer includes a first top surface disposed inside the first wiring layer and a second top surface having a height difference from the first top surface.

9. The image sensor of claim 1, further comprising:
a first color filter disposed on the first region of the second substrate; and
a second color filter disposed on the conductive pattern on the second region of the second substrate.

10. The image sensor of claim 1, further comprising:
a first color filter disposed on the first region of the second substrate; and
an organic photoelectric conversion layer disposed on the first color filter.

11. The image sensor of claim 1, further comprising:
a first color filter disposed on the first region of the second substrate; and
a microlens disposed on the first color filter,
wherein one microlens is disposed on at least two of the first color filters.

12. An image sensor comprising:
a first substrate;
a first wiring structure disposed on the first substrate, the first wiring structure including a first interlayer insulating layer and a first wiring layer disposed inside the first interlayer insulating layer;
a second wiring structure disposed on the first wiring structure and including a second wiring layer;
a second substrate disposed on the second wiring structure, the second substrate including a first region and a second region that are spaced apart from each other, the first region including a photoelectric conversion element disposed therein;
a connection trench penetrating the second region of the second substrate, extending into the first wiring layer, and exposing at least a partial portion of the second wiring layer; and
a conductive pattern disposed along a sidewall and a bottom surface of the connection trench, the conductive pattern including a first portion directly contacting a top surface of the first wiring layer and a second portion directly contacting a top surface of the second wiring layer,
wherein the first portion of the conductive pattern includes a first bottom surface disposed inside the first wiring layer and a second bottom surface having a height difference from the first bottom surface.

13. The image sensor of claim 12, wherein a height of the second bottom surface of the first portion of the conductive pattern is substantially same as a height of the top surface of the first wiring layer.

14. The image sensor of claim 12, wherein at least a partial portion of the first bottom surface of the first portion of the conductive pattern directly contacts the first interlayer insulating layer.

15. The image sensor of claim 12, wherein the second portion of the conductive pattern includes a third bottom surface disposed inside the second wiring layer and a fourth bottom surface having a height difference from the third bottom surface.

16. The image sensor of claim 12, wherein the connection trench comprises:
a first connection trench penetrating the second wiring structure and extending into the first wiring layer; and
a second connection trench extending into the second wiring layer and spaced apart from the first connection trench.

17. The image sensor of claim 12, further comprising:
an adhesive layer disposed on the conductive pattern; and
a low refractive index layer disposed on the adhesive layer to fill the connection trench.

18. The image sensor of claim 12, further comprising:
a first color filter disposed on the first region of the second substrate; and
an organic photoelectric conversion layer disposed on the first color filter.

19. An image sensor comprising:
a first substrate;
a first wiring structure disposed on the first substrate and including a first wiring layer;
a second wiring structure disposed on the first wiring structure and including a second wiring layer;
a second substrate disposed on the second wiring structure and including a first region and a second region that are spaced apart from each other, the first region including a photoelectric conversion element disposed therein; and
a connection trench penetrating the second region of the second substrate and exposing each of the first wiring layer and the second wiring layer; and
a conductive pattern disposed along a sidewall and a bottom surface of the connection trench, and having a step in the bottom surface of the connection trench exposing the first wiring layer,
wherein the conductive pattern includes a first bottom surface that is a lowermost surface of the conductive pattern and a second bottom surface having a height difference from the first bottom surface, and
wherein the first bottom surface of the conductive pattern is disposed at a higher level than a level of the bottom surface of the first wiring layer.

20. The image sensor of claim 19, further comprising a metal layer disposed between the second bottom surface of the conductive pattern and the first wiring layer in the connection trench.
